(19) United States
(12) Patent Application Publication
(10) Pub. No.: US 2024/0128337 A1
(43) Pub. Date: Apr. 18, 2024

(54) SEMICONDUCTOR TRANSISTOR AND MANUFACTURING METHOD THEREFOR

(71) Applicant: XIAMEN SAN'AN INTEGRATED CIRCUIT CO., LTD., Xiamen (CN)

(72) Inventors: Shenghou LIU, Xiamen (CN); Kechuang LIN, Xiamen (CN); Xiguo SUN, Xiamen (CN)

(21) Appl. No.: 18/395,575

(22) Filed: Dec. 24, 2023

Related U.S. Application Data
(63) Continuation of application No. PCT/CN2022/118891, filed on Sep. 15, 2022.

(30) Foreign Application Priority Data
Dec. 15, 2021 (CN) 2021115385045

(51) Int. Cl. H01L 29/417; H01L 21/02; H01L 21/225; H01L 29/45

(52) U.S. Cl. CPC H01L 29/41766; H01L 21/02362; H01L 21/2253; H01L 29/45

(57) ABSTRACT

Provided are a transistor with low contact resistivity and a manufacturing method therefor. The transistor includes a substrate, a buffer layer, a channel layer and a barrier layer sequentially stacked, an ion implantation region is formed in a source region and a drain region of the barrier layer, and grooves arranged at intervals are formed in the ion implantation region. Ohmic metal is deposited on a surface of the ion implantation region and in each groove, and the ohmic metal is in contact with a bottom and a side wall of each groove. In this solution, the ohmic metal can be not only in contact with the surface of the ion implantation region, but also in contact with the side wall of each of the grooves, thereby increasing a contact area between the ohmic metal and the semiconductor, and thus reducing the ohmic contact resistivity.

### TECHNICAL FIELD

The present disclosure relates to the technical field of semiconductors, and particularly to a semiconductor transistor with low contact resistivity and a manufacturing method therefor.

### BACKGROUND

A high electron mobility transistor (HEMT) has the advantages of high frequency, high voltage, and high temperature, and is the future development direction of solid-state microwave power devices and power electronic devices. Further, the performance of ohmic contact has a great influence on the performance of HEMT devices, and how to reduce ohmic contact resistivity of the HEMT devices is very important to improve the performance of the HEMT devices. However, because gallium nitride (GaN) in the HEMT devices has high stability, GaN is not easy to have chemical reaction, and thus ohmic contact is not easier to be formed.

In the existing methods, a high-temperature alloy process is usually used to reduce ohmic contact resistivity. However, during high-temperature alloy process, particulate matter is easy to be produced, which makes surfaces of corresponding HEMT device and ohmic metal rough, and then leads to the appearance of a spike electric field, which reduces breakdown characteristics of the HEMT device.

### SUMMARY

Objectives of the present disclosure are providing a transistor with low contact resistivity and a manufacturing method therefor, which can reduce ohmic contact resistivity and avoid the problem that burrs are generated on a surface of the transistor and thus the performance of the transistor is affected.

An embodiment of the present disclosure provides a semiconductor transistor, including a semiconductor epitaxial layer, where the semiconductor epitaxial layer includes a channel layer and a barrier layer sequentially stacked on a substrate; and at least one of a source region and a drain region of the semiconductor epitaxial layer is provided with an ion implantation region therein, and the ion implantation region is provided with a groove; ohmic metal is disposed on the ion implantation region, and the ohmic metal is in ohmic contact with a non-groove region of the ion implantation region, a sidewall of the groove, and a bottom of the groove; an area of a vertical projection of the groove on the substrate is greater than or equal to half of an area of a vertical projection of the ohmic metal on the substrate; and a depth of that groove is less than a depth of the ion implantation region.

The semiconductor transistor provide by the present disclosure can provide a low contact resistivity. The semiconductor transistor includes a substrate, a buffer layer, a channel layer and a barrier layer are sequentially stacked. An ion implantation region is formed in a source region and a drain region of the barrier layer. Grooves arranged at intervals are defined in the ion implantation region. An extension direction of each of the grooves is a direction from the barrier layer to the channel layer. Ohmic metal is deposited on a surface of the ion implantation region and in each groove, and the ohmic metal is in contact with a bottom and a side wall of each groove. In this solution, by defining the grooves, the ohmic metal can be not only in contact with the surface of the ion implantation region, but also in contact with the side wall of each of the grooves, thereby increasing a contact area between the ohmic metal and the semiconductor, and thus reducing the ohmic contact resistivity. The ohmic contact resistivity can be further reduced by forming the ion implantation region through ion implantation. An annealing process is not needed, thereby avoiding the problem that burrs are generated on a surface of the semiconductor transistor and thus the performance of the semiconductor transistor is affected.

### BRIEF DESCRIPTION OF DRAWINGS

In order to explain technical solutions of embodiments of the present disclosure more clearly, the following accompanying drawings will be briefly introduced hereinafter. It should be understood that the following accompanying drawings merely show some embodiments of the present disclosure, and should not be regarded as limiting the scope of protection of the present disclosure. For the skilled in the art, other related drawings can be obtained according to these introduced drawings without creative work.

FIG. 1 illustrates a schematic structural view of a transistor with low contact resistivity according to an embodiment of the present disclosure.

FIG. 2 illustrates a schematic structural view of a transistor with an ion implantation region.

FIG. 3 illustrates a schematic plan view of FIG. 1 taken from a direction AA′.

FIG. 4 illustrates a schematic flowchart of a manufacturing method for a transistor with low contact resistivity according to an embodiment of the present disclosure.

FIG. 5 through FIG. 10 illustrate schematic views of device structures formed by various steps in a manufacturing method for a transistor with low contact resistivity according to an embodiment of the present disclosure.

FIG. 11 illustrates a schematic view of a transistor according to an embodiment of the present disclosure, in which peripheral grooves thereof have smaller sizes and internal grooves have greater sizes.

FIG. 12 illustrates a schematic enlarged view of a region X1 of the transistor of FIG. 11.

FIG. 13 illustrates a schematic enlarged view of a region X2 of the transistor of FIG. 11.

FIG. 14 illustrates a schematic view of a transistor, in which a spacing between two adjacent grooves proximate to a gate region is smaller than a spacing between adjacent grooves facing away from the gate region.

FIG. 15 illustrates a schematic enlarged view of a region X3 of the transistor of FIG. 14.

FIG. 16 illustrates a schematic enlarged view of a region X4 of the transistor of FIG. 14.

FIG. 17 and FIG. 18 illustrate schematic views of a transistor according to an embodiment of the present disclosure, in which grooves thereof have the same size and the grooves are each cylindrical.

FIG. 19 illustrates a schematic view of a transistor according to an embodiment of the present disclosure, in which grooves thereof have the same size and each of the grooves is a truncated cone.

FIG. 20 illustrates a schematic view of a transistor according to an embodiment of the present disclosure, in which grooves thereof are cuboid.

FIG. 21 illustrates a schematic view of a transistor according to an embodiment of the present disclosure, in which grooves thereof are cuboid, and a spacing between two adjacent grooves facing towards a gate region is smaller than a spacing between adjacent grooves facing away from the gate region.

FIG. 22 illustrates a schematic enlarged view of a region X5 of the transistor of FIG. 21.

FIG. 23 illustrates a schematic enlarged view of a region X6 of the transistor of FIG. 21.

### DETAILED DESCRIPTION OF EMBODIMENTS

In order to make the objectives, technical solutions, and advantages of the embodiments of the present disclosure more clearly, the technical solutions in the embodiments of the present disclosure will be described clearly and completely in combination with the accompanying drawings. Apparently, the described embodiments are merely parts of embodiments of the present disclosure, but not the whole embodiments. Components of the embodiments of the present disclosure, which are generally described and illustrated in the accompanying drawings herein, can be arranged and designed in various different configurations.

Therefore, the following detailed description of the embodiments of the present disclosure in combination with the accompanying drawings is not intended to limit the scope of protection of the present disclosure, but the embodiments of the present disclosure merely represent selected embodiments of the present disclosure. Based on the described embodiments of the present disclosure, all other embodiments obtained by the skilled in the art without creative work belong to the scope of protection of the present disclosure.

It should be noted that similar symbols and letters indicate similar items in the following drawings, therefore, once an element is defined in one drawing, it does not need to be further defined and explained in subsequent drawings.

In the description of the present disclosure, it should be noted that if an orientation or positional relationship indicated by any term of “upper”, “lower”, “inner” and “outer” is based on the orientation or positional relationship shown in the accompanying drawings, or is the orientation or positional relationship that a corresponding product of the present disclosure is usually put in use, it is only for the convenience of describing the present disclosure and simplifying the description, and it does not indicate or imply that a device or element referred to must have a specific orientation, be constructed and operated in a specific orientation, and thus it should be not understood as the limiting of the present disclosure.

It should be noted that features in the embodiments of the present disclosure can be combined with each other without conflict.

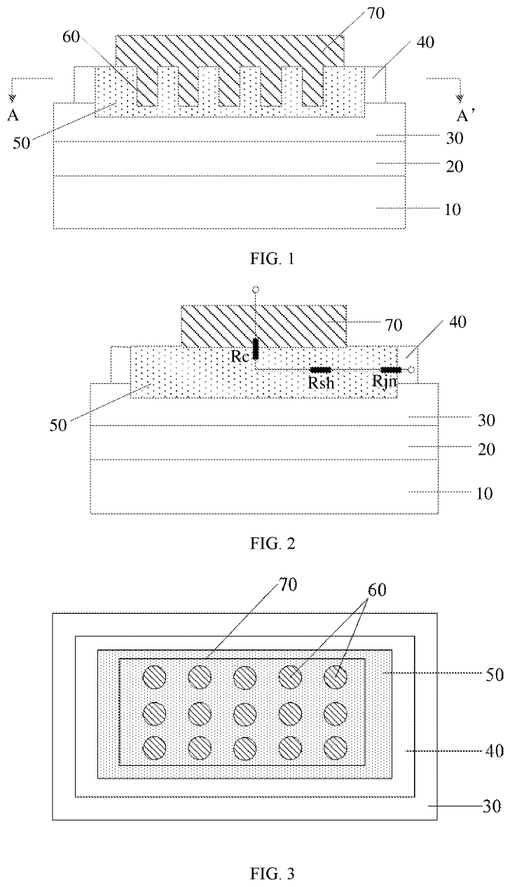

As illustrated in FIG. 1, FIG. 1 illustrates a schematic structural view of a transistor with low contact resistivity according to an embodiment of the present disclosure. The transistor includes a substrate 10. The substrate 10 may be any one of a GaN substrate, a SiC substrate, a sapphire substrate, or a Si substrate, or may be any other substrate suitable for epitaxial growth of GaN known to the skilled in the art, which is not limited herein.

The transistor further includes a buffer layer 20 formed on the substrate 10, and the buffer layer 20 may be a single-layer structure or a multi-layer structure. When the buffer layer 20 is a multi-layer structure, the multilayer structure can alleviate a stress caused by lattice mismatch. The multilayer structure may include an electron isolation layer, which is used to avoid the phenomenon that parallel conductance is formed outside a conductive channel when the transistor works, and avoid the problem that the electron mobility of the transistor decreases.

A channel layer 30 and a barrier layer 40 (also together referred to as a semiconductor epitaxial layer) are sequentially stacked on a side of the buffer layer 20 facing away from the substrate 10. In an embodiment, the channel layer 30 is made of GaN, and the barrier layer 40 is made of the AlGaN. An active region is defined on a surface of the barrier layer 40, and the active region includes a gate region, a source region and a drain region. The source region and the drain region are located at two opposite sides of the gate region, respectively. The channel layer 30 and the barrier layer 40 form a heterojunction, and alternatively, the barrier layer 40 can be made of AlN, InN, InAlN and InAlGaN, and the channel layer 30 can be made of AlGaN.

In an embodiment, each of the source region and the drain region of the barrier layer 40 are provided with an ion implantation region 50 by ion implantation (only a part of the transistor is shown in the FIG. 1, which shows the ion implantation region 50 corresponding to the source region, or the ion implantation region 50 corresponding to the drain region), that is, the ion implantation region 50 is formed by ion implantation of the barrier layer 40 based on each of the source region and the drain region of the barrier layer 40. By ion implantation to form the ion implantation region 50, a contact resistance between ohmic metal 70 and a semiconductor (i.e., the semiconductor epitaxial layer) can be reduced.

As illustrated in FIG. 2, when the ion implantation region 50 is formed in the barrier layer 40, an overall resistivity of the transistor is OC_Rc=Rc+Rsh+Rjn, where Rc represents a contact resistivity between the ohmic metal 70 and the semiconductor (i.e., the semiconductor epitaxial layer), Rsh represents a resistivity of the ion implantation region 50, and Rjn represents a resistivity between the ion implantation region 50 and the barrier layer 40. By forming the ion implantation region 50 as described above, compared with the traditional structure (i.e., the structure without ion implantation), the resistivity of the ion implantation region 50 and the resistivity between the ion implantation region 50 and the barrier layer 40 are lower than that a resistivity of a barrier layer in the traditional structure. In order to further reduce the overall resistivity of the transistor, it is necessary to reduce the contact resistivity Rc between ohmic metal 70 and the semiconductor (i.e., the semiconductor epitaxial layer).

Therefore, in order to further reduce the overall resistivity of the transistor, on the basis of the above, grooves 60 are defined at intervals in the ion implantation region 50 in the transistor, and an extension direction of each groove 60 is a direction from the barrier layer 40 to the channel layer 30. That is, each groove 60 is formed by etching in the direction from the barrier layer 40 to the channel layer 30.

On this basis, the transistor also includes ohmic metal 70. The ohmic metal 70 is deposited on a surface of the ion implantation region 50 and deposited in each groove 60. The ohmic metal 70 is in contact with the surface of the ion implantation region 50 and also in contact with a bottom and a side wall of each groove 60. Specifically, the ohmic metal 70 can be formed by deposition of titanium (Ti)/aluminum (Al)/nickel (Ni)/aurum (Au). The deposited Ohmic metal 70 is used to form a source electrode and a drain electrode.

It should be noted that the transistor provided in the embodiments of the present disclosure can include other structures such as a gate electrode in addition to the above-mentioned structures, and other structures are arranged in a conventional manner in the related art, which is repeated herein. In addition, an epitaxial structure of the transistor provided in the embodiments can also be applied to HEMT structures made of other materials.

In the transistor provided by the embodiments of the present disclosure, the ion implantation region 50 is formed in each of the source region and the drain region of the epitaxial layer by ion implantation, which can effectively reduce resistivity of ohmic contact. In addition, a high-temperature annealing process is not needed to be performed on the source electrode and the drain electrode, thereby avoiding the problem that burrs are generated on a surface of the transistor and thus the performance of the transistor is affected.

On this basis, since the grooves 60 are formed in the ion implantation region 50, the ohmic metal 70 can be in contact with the surface of the ion implantation region 50 and bottoms and side walls of the grooves 60. Under the condition that the specification of the transistor is unchanged, ohmic metal of an original transistor is only capable of being in contact with a surface of a corresponding ion implantation region, while for the transistor in the embodiments of the present disclosure, the ohmic metal 70 can be not only in contact the surface of the ion implantation region 50 and the bottoms of the grooves 60 (equivalent to the surface of the corresponding ion implantation region of the original transistor), but also in contact the side walls of the grooves 60, thereby effectively increasing a contact area between the metal (i.e., the ohmic metal 70) and the semiconductor (i.e., the semiconductor epitaxial layer), and further reducing the contact resistivity.

In an embodiment, the ion implantation region 50 are formed in the barrier layer 40, implanted ions include at least one selected from the group consisting of silicon (Si) ions and germanium (Ge) ions, and the implanted ions can be implanted by an ion implanter using an ion source. Commonly used ion implanters include a low-energy high-beam ion implanter, a high-energy ion implanter, and a medium-beam ion implanter. Specifically, a beam current of the low-energy high-beam ion implanter can reach several milliamps or even dozens of milliamps, and an implantation dose of ion can range from 1×10¹³/cm² to 1×10¹⁶/cm². In the embodiments of the present disclosure, the low-energy high-beam ion implanter can be used for ion implantation, and the ion implantation dose is in a range from 1×10¹⁴/cm² to 1×10¹⁶/cm².

A depth of the ion implantation region 50 may be less than or equal to a thickness of the barrier layer 40, that is, in a longitudinal direction, a position (i.e., a lower position) corresponding to a depth of ion implantation may be located at a middle position of the barrier layer 40 or at a surface of the channel layer 30. Alternatively, the depth of the ion implantation region 50 may be greater than the thickness of the barrier layer 40, but less than 500 nanometers (nm), that is, the ion implantation region 50 may penetrate through the barrier layer 40 and extend to the channel layer 30.

In an embodiment of the present disclosure, the channel layer 30 is made of GaN, and the barrier layer 40 is made of AlGaN, as such, when the implanted ions are the Si ions, an activation rate of the Si ions in GaN is higher than that in AlGaN, so a resistance of Si ions implanted into GaN is lower than that of Si ions implanted into AlGaN. Based on this, in this embodiment, the depth of the ion implantation region 50 can be set to be greater than the thickness of the barrier layer 40 and less than 500 nm.

In addition, in an embodiment of the present disclosure, the grooves 60 are defined by etching the ion implantation region 50, and a direction for the etching is a direction from the barrier layer 40 to the channel layer 30. Specifically, the grooves 60 can be arranged in an array, for example, in an array with rows and columns, as shown in FIG. 3. Of course, the grooves 60 can be also arranged in an annular array, which is not limited herein.

In order to reduce the contact resistivity of the ohmic metal 70 as much as possible, a duty ratio of the grooves 60 in the whole area of the ohmic metal 70 may be limited. In one implementation, a sum of areas of vertical projections of the grooves 60 on the substrate 10 is greater than or equal to half of a surface area of the ohmic metal 70 (i.e., an area of a vertical projection of the ohmic metal 70 on the substrate 10).

For example, if an area of a vertical projection of each groove 60 on the substrate 10 is a, the number of the grooves 60 is k, and the surface area of the ohmic metal 70 is b, then b/2≤(k×a)<b, that is, 0.5≤(k×a)/b<1. In this way, it is ensured that the duty ratio of the grooves 60 can reach a certain level, such that it can be ensured that, the contact area between the ohmic metal 70 and the semiconductor (i.e., the semiconductor epitaxial layer) can be increased, and the purpose of effectively reducing the contact resistivity can be further achieved.

In an embodiment, a size of the vertical projection of each groove 60 on the substrate may be between 1 μm and 100 μm. The number of the grooves 60 can be determined according to the size of each of the grooves 60, the duty ratio of the grooves 60, and an area of a vertical projection of the ohmic metal 70 on the substrate. Specifically, the vertical projection of each groove 60 on the substrate can be circular, rectangular, square or other irregular shape. When the vertical projection is circular, the size is a diameter; when the vertical projection is rectangular or square, the size is a diagonal length; and when the vertical projection is in other irregular shape, the size is the longest distance between any two points on an edge of an image of the vertical projection.

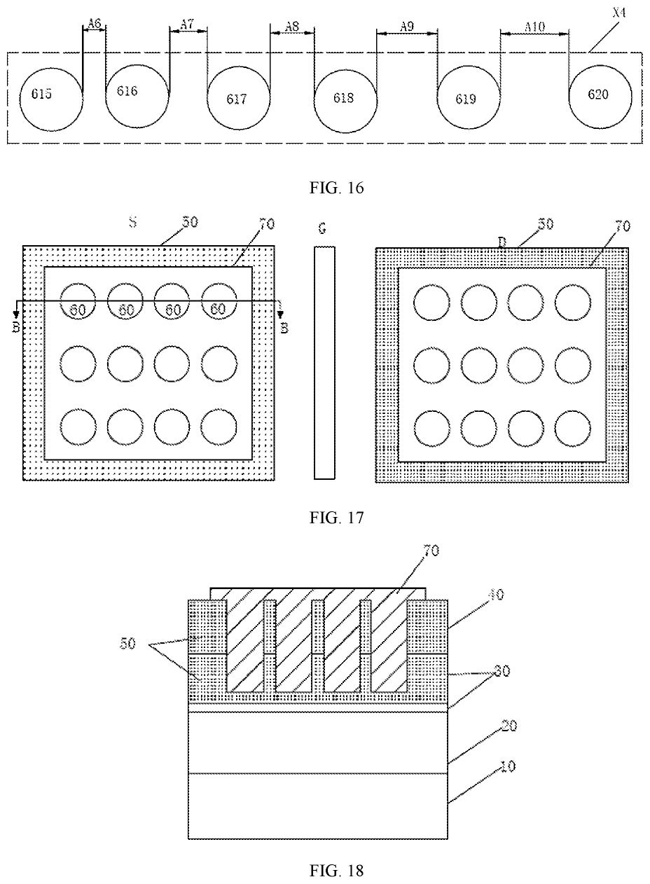

In an embodiment, a size of each groove 60 may be the same, as shown in FIG. 16 and FIG. 17.

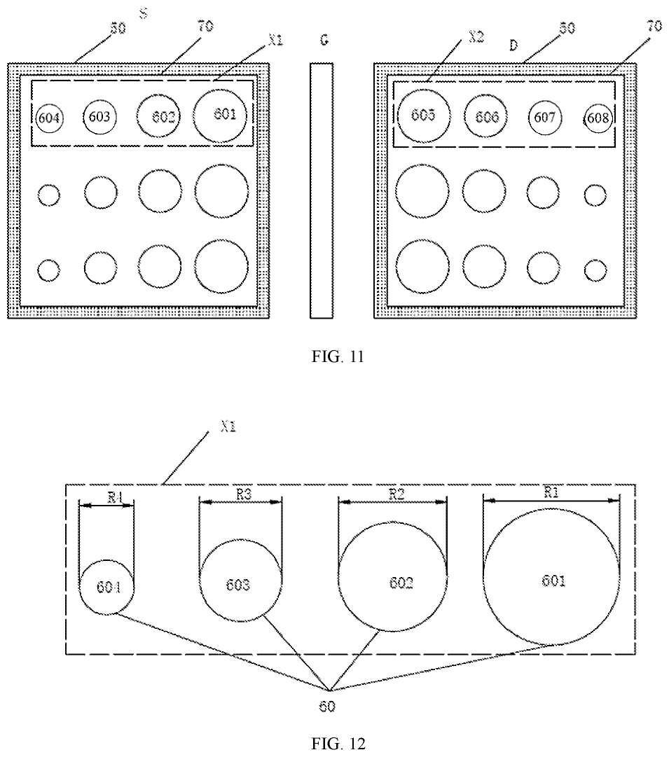

In an embodiment, sizes of the grooves 60 vary from small to large along a current flow direction. As shown in FIG. 11 through FIG. 13, from a periphery to an inside of the grooves 60, a size of a groove at the periphery is smaller and a size of a groove at the inside is larger. For example, the size may be gradually enlarged according to a certain proportion, or may be randomly enlarged, which is not limited in the embodiments of the present disclosure. In this way, due to the current edge-crowding effect, a current for ohmic contact is mainly concentrated in an edge position of ohmic metal. Therefore, under the same duty cycle, the equivalent contact area increases, the contact resistivity can be reduced more effectively.

Furthermore, in an embodiment, a spacing between each two adjacent grooves may be the same.

In an embodiment, the transistor includes a source region S, a drain region D, and a gate region G. The ion implantation region 50 includes grooves 60 with different sizes, and a size of a groove proximate to the gate region G is larger than that a size of a groove facing away from the gate region G. As shown in FIG. 11, a region X1 of the source region S includes grooves 601-604, in which the groove 601 is closest to the gate region G, and vertical projections of the grooves 601-604 on the substrate are circular. As shown in FIG. 12, sizes of the groove 601, the groove 602, the groove 603 and the groove 604 are R1, R2, R3 and R4, respectively, and R1>R2>R3>R4. As shown in FIG. 11, a region X2 of the drain region D includes grooves 605-608, in which the groove 605 is closest to the gate region G, and vertical projections of the grooves 605-608 on the substrate is circular. As shown in FIG. 13, sizes of the groove 605, the groove 606, the groove 607 and the groove 608 are R5, R6, R7 and R8, respectively, and R5>R6>R7>R8.

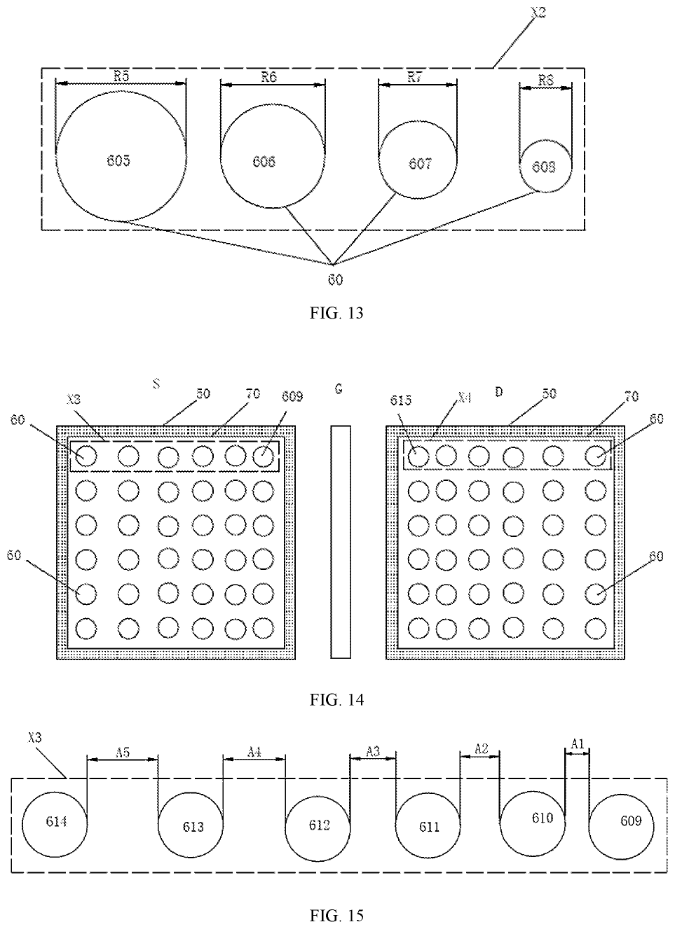

In an embodiment, the transistor includes a source region S, a drain region D, and a gate region G. The ion implantation region 50 includes grooves 60 with the same size, and a spacing between two adjacent grooves proximate to the gate region G is smaller than a spacing between two adjacent grooves facing away from the gate region G. As shown in FIG. 14 through FIG. 16, vertical projections of the grooves on the substrate is circular, and a region X3 of the source region S includes grooves 609 to 614. The groove 609 is closest to the gate region G. As shown in FIG. 15, a spacing between the groove 609 and the groove 610 is A1, a spacing between the groove 610 and the groove 611 is A2, a spacing between the groove 611 and the groove 612 is A3, a spacing between the groove 612 and the groove 613 is A4, a spacing between the groove 613 and the groove 614 is A5, and A5>A4>A3>A2>A1. As shown in FIG. 16, a region X4 of the drain region D includes grooves 615-620, the groove 615 is closest to the gate region G, a spacing between the groove 615 and the groove 616 is A6, a spacing between the groove 616 and the groove 617 is A7, a spacing between the groove 617 and the groove 618 is A8, a spacing between the groove 618 and the groove 619 is A9, a spacing between the groove 619 and the groove 620 is A10, and A10>A9>A8>A7>A6. It should be noted that in other embodiments, a spacing between two adjacent grooves proximate to the gate region G is smaller than a spacing between two adjacent grooves facing away from the gate region G, and sizes of vertical projections of the grooves on the substrate are different.

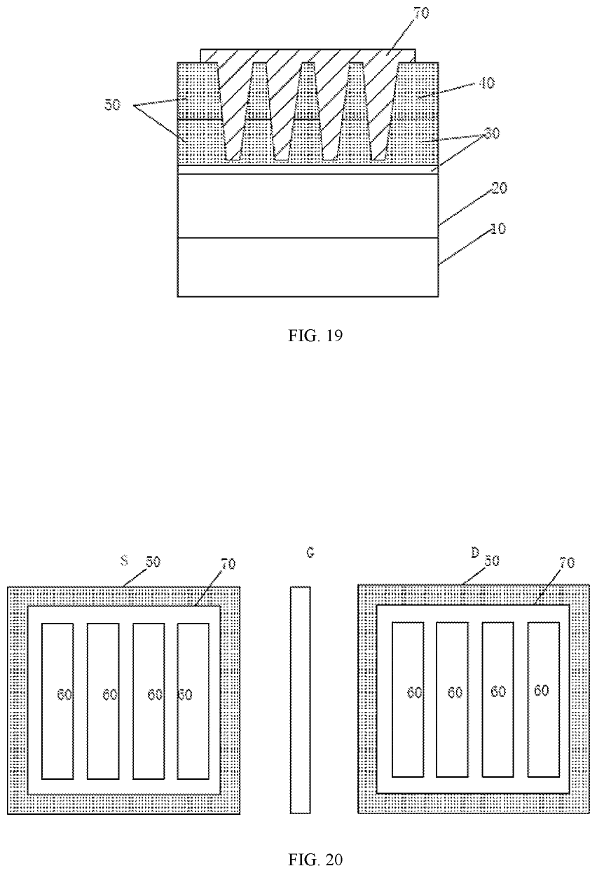

In an embodiment, as shown in FIG. 17, the transistor includes a source region S, a drain region D, and a gate region G. The ion implantation region 50 includes grooves 60 with the same size. As shown in FIG. 18, the grooves 60 penetrate into the channel layer 30 through the barrier layer 40 to make a depth of the ion implantation region 50 extend into the channel layer 30. The grooves can be cylindrical, as shown in FIG. 18, or each of the grooves is a truncated cone, as shown in FIG. 19, which is narrow near the substrate and wide facing away from the substrate. It should be noted that it can also be understood that the vertical projection of the groove on the substrate can also have other shapes, for example, the groove is narrow near the substrate and wide facing away from the substrate.

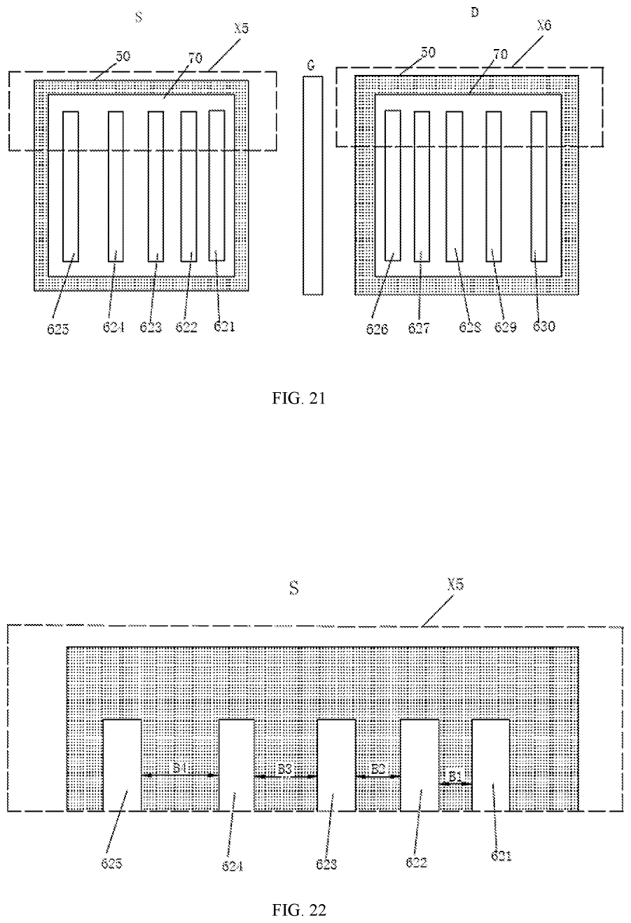

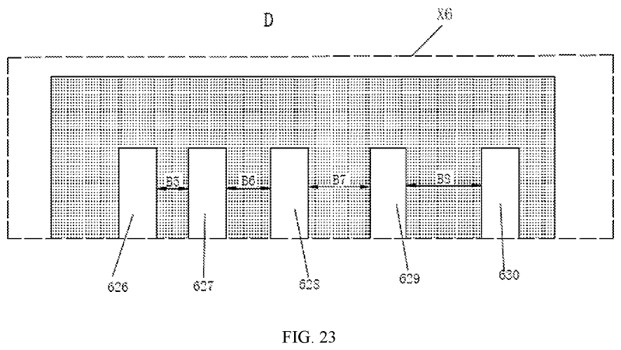

In an embodiment, the transistor includes a source region S, a drain region D, and a gate region G. The ion implantation region 50 includes grooves 60 with the same size, and a spacing between each two adjacent grooves is the same, as shown in FIG. 20. In an embodiment, as shown in FIG. 21, the transistor includes a source region S, a drain region D, and a gate region G. The ion implantation region 50 includes grooves 60 with the same size, and a spacing between two adjacent grooves proximate to the gate region G is smaller than a spacing between two adjacent grooves facing away from the gate region G. A vertical projection of each of the grooves on the substrate is rectangular, and a region X5 of the source region S includes grooves 621-625. The groove 621 is closest to the gate region G. As shown in FIG. 22, a spacing between the groove 621 and the groove 622 is B1, a spacing between the groove 622 and the groove 623 is B2, a spacing between the groove 623 and the groove 624 is B3, a spacing between the groove 624 and the groove 625 is B4, and B4>B3>B2>B1. A region X6 of the drain region D includes grooves 626-630, and the groove 626 is closest to the gate region G. As shown in FIG. 23, a spacing between the groove 626 and the groove 627 is B5, a spacing between the groove 627 and the groove 628 is B6, a spacing between the groove 628 and the groove 629 is B7, a spacing between the groove 629 and the groove 630 is B8, and B8>B7>B6>B5. It should be noted that in other embodiments, the sizes of the vertical projections of the grooves on the substrate may also be different.

Without considering the performance optimization, the sizes of the grooves can also be changed at will.

In a specific implementation, any one of the above embodiments can be adopted, which is not limited herein.

A vertical projection of each groove 60 on the substrate can be circular (as shown in FIG. 11 through FIG. 17), rectangular (as shown in FIG. 20 and FIG. 21), square or other irregular shape. As shown in FIG. 11 through FIG. 14, the vertical projection of each groove 60 on the substrate can be circular, which is helpful for the ohmic metal 70 deposited therein to be in good contact with a sidewall of the groove 60, so as to increase a contact area between the metal (i.e., the ohmic metal 70) and the semiconductor (i.e., the semiconductor epitaxial layer).

In an embodiment, a depth of each groove 60 formed by etching may be greater than a thickness of the barrier layer 40 and less than 500 nm. In this way, a lower part of the ohmic metal 70 can be in contact with GaN at a bottom of the groove 60 and in contact with GaN on a sidewall of a lower part of the groove 60, and thus a contact resistance between the ohmic metal 70 and GaN is lower.

For any transistor with low contact resistivity provided by the embodiments, combined with the ion implantation region 50 formed by ion implantation and the grooves 60 formed in the ion implantation region 50, the contact area between the ohmic metal 70 and the semiconductor (i.e., the semiconductor epitaxial layer) can be effectively increased, thereby effectively reducing the contact resistivity, and avoiding the generation of burrs on a surface of the transistor caused by the ohmic contact process formed by high temperature annealing in the related art, thus ensuring the good performance of the transistor.

Please refer to FIG. 1 and FIG. 4, an embodiment of the present disclosure also provides a manufacturing method for a transistor with low contact resistivity, which can be used for manufacturing any one transistor with low contact resistivity described above. The detailed process of the method will be described below.

The manufacturing method includes the following steps:
S101, sequentially forming a substrate 10, a buffer layer 20, a channel layer 30, and a barrier layer 40;
S102, forming, by ion implantation, an ion implantation region 50 in each of a source region and a drain region of the barrier layer 40;
S103, etching the ion implantation region 50 to define grooves 60 arranged at intervals, where an extension direction of each of the grooves 60 is a direction from the barrier layer 40 to the channel layer 30; and
S104, depositing ohmic metal 70 on a surface of the ion implantation region 50 and in each groove 60, where the ohmic metal 70 is in contact with a bottom and a sidewall of each groove 60.

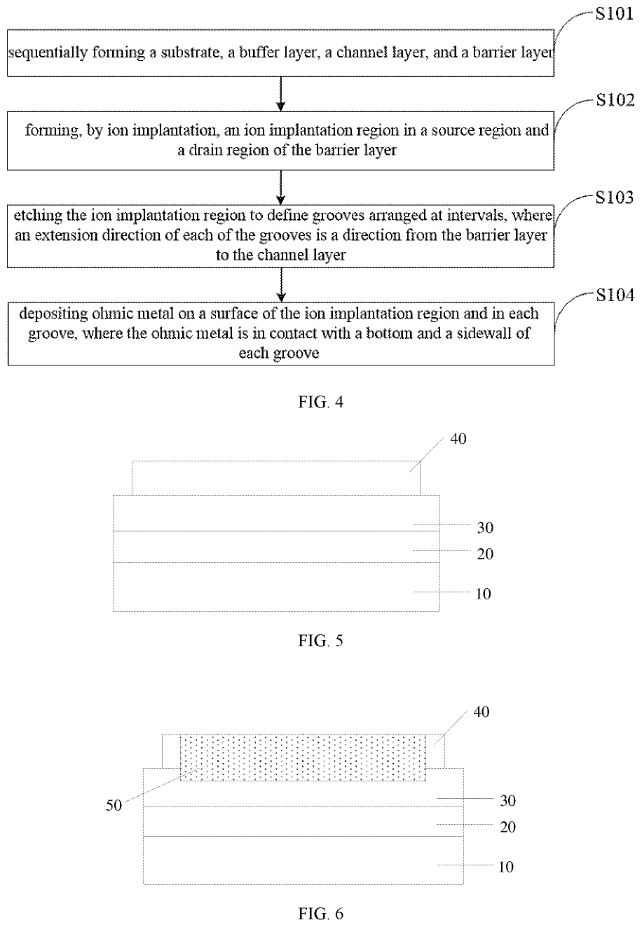

In the step S101, please refer to FIG. 5, the substrate 10 can be a SiC substrate, a Si substrate, a sapphire substrate, or a GaN substrate. The buffer layer 20, the channel layer 30, and the barrier layer 40 can be deposited on the substrate 10 in sequence, and any one of the deposition methods such as plasma enhanced chemical vapor deposition (PECVD), low pressure chemical vapor deposition (LPCVD) and inductively coupled plasma-enhanced chemical vapor deposition (ICP-PECVD) can be adopted.

Specifically, T the buffer layer 20 may be a single-layer structure or a multi-layer structure. When the buffer layer 20 is a multi-layer structure, the multi-layer structure may include an electron isolation layer, which is used to avoid the phenomenon that parallel conductance is formed outside a conductive channel when the transistor works, and to avoid the problem that the electron mobility of the transistor decreases.

In an embodiment, the channel layer 30 is made of GaN, and the barrier layer 40 is made of the AlGaN.

In the step S102, referring to FIG. 6, an active region is defined on a surface of the barrier layer 40, and the active region includes a gate region, a source region and a drain region. Ion implantation is performed on the barrier layer 40 based on the source and drain regions on the barrier layer 40. The implanted ions can be Si ions and/or Ge ions. For example, a low-energy high-beam ion implanter can be used, and Si ions and/or Ge ions are used as ion sources to perform ion implantation and activation on the barrier layer 40 based on the source region and the drain region.

During ion implantation, single implantation energy or multiple implantation energies can be used for implantation. In an embodiment, during ion implantation, an ion implantation dose can be in a range from 1×10¹⁴/cm² to 1×10¹⁶/cm².

A position (i.e., a lower position) corresponding to a depth of ion implantation may be located at a middle position of the barrier layer 40, that is, the depth of the ion implantation region 50 may be less than a thickness of the barrier layer 40. In addition, a position corresponding to a depth of the ion implantation region 50 may also be located at a surface of the channel layer 30, that is, the depth of the ion implantation region 50 may be equal to a thickness of the barrier layer 40. Alternatively, a position corresponding to a depth of the ion implantation region 50 may be located at a middle position of the channel layer 30, that is, a depth of the ion implantation region 50 may be greater than the thickness of the barrier layer 40. However, in order to reduce the difficulty in the fabrication process, the depth of the ion implantation region 50 may be greater than the thickness of the barrier layer 40 and less than 500 nm.

In an embodiment, when ion implantation is performed, a position corresponding to the depth of ion implantation may be located at the middle position of the channel layer 30. Because the channel layer 30 is made of GaN and the barrier layer 40 is made of AlGaN. When the implanted ions are the Si ions, an activation rate of the Si ions in GaN is higher than that in AlGaN, so t a resistance of Si ions implanted into GaN is lower than that of Si ions implanted into AlGaN.

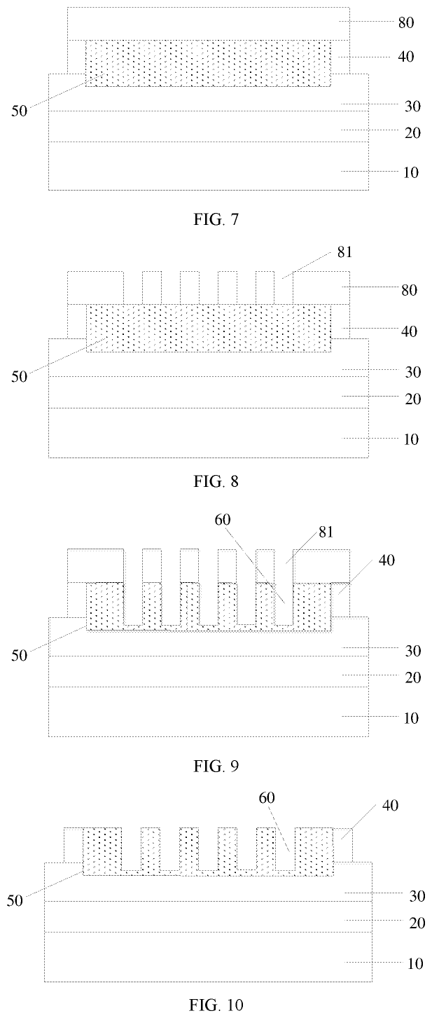

In the step S103, please refer to FIG. 7, the grooves 60 can be prepared and formed in the ion implantation region 50 by photolithography development and etching. First, a photoresist layer 80 may be formed on an upper surface of the barrier layer 40 through a photolithography process. A photomask containing holes may be used, and positions of the holes of the photomask correspond to a position of the ion implantation region 50 on the barrier layer 40. In this way, the photoresist layer 80 is exposed and developed by using the photomask. When the photoresist layer 80 is made of a positive photoresist material, portions of the photoresist layer 80 corresponding to the positions of the holes in the photomask are dissolved under illumination, while other portions of the photoresist layer 80 corresponding to other parts of the photomask excepting for the holes remain. Thus, as shown in FIG. 8, through holes 81 are formed on the photoresist layer 80 to expose the ion implantation region 50 below the photoresist layer 80. In the step S103, please refer to FIG. 9, etching can be performed on portions of the ion implantation region 50 corresponding to positions of the through holes 81 of the photoresist layer 80, so as to form the grooves 60 in the ion implantation region 50. In this step, the etching can be performed by inductively coupled plasma (ICP) in a certain gas atmosphere, such as CF₄, CHF₃, O₂, N₂ and other gases. A direction for the etching of the ion implantation region 50 is a direction from the barrier layer 40 to the channel layer 30.

The depth of each etched groove 60 can be greater than the thickness of the barrier layer 40 and less than 500 nm, so that a bottom of a ohmic metal 70 subsequently deposited in the groove 60 can be in contact with the channel layer 30 made of GaN, and sides of a lower part of the ohmic metal 70 can be in contact with the channel layer 30 made of GaN on a sidewall of the groove 60, thereby making the contact resistivity between the ohmic metal 70 and the semiconductor (i.e., the semiconductor epitaxial layer) lower.

Specifically, shapes of vertical projections of the grooves 60 on the substrate can be determined according to the holes in the photomask, for example, the shape of the vertical projection of each groove 60 on the substrate can be circular, rectangular, square or other irregular shapes. In addition, a size of the vertical projection of each groove 60 on the substrate is also determined by a size of the hole of the photomask. In this embodiment, the size of the vertical projection of each groove 60 on the substrate can be between 1 μm and 100 μm.

In an embodiment, the grooves 60 can be arranged in an array, such as in a multi-row and multi-column array or a circular array. In order to effectively increase the contact area between the ohmic metal 70 and the semiconductor (i.e., the semiconductor epitaxial layer), the groove 60 should have a certain duty ratio in the ion implantation region 50. For example, a sum of areas of the grooves 60 is more than half of an area of the ion implantation region 50.

After completing the above steps, the photoresist layer 80 on the barrier layer 40 can be removed. For example, an organic solvent, such as N-methylpyrrolidone, can be used to remove a residual photoresist after etching, at a temperature of 70 degrees Celsius (° C.) and a pressure of 1000 pounds per square inch (PSI) to obtain a device structure as shown in FIG. 10.

In the step S104, please refer to FIG. 1, in an embodiment, the ohmic metal 70 can be formed by evaporating metal Ti/Al/Ni/Au on the surface of the ion implantation region 50.

The formed ohmic metal 70 may be in contact with the surface of the ion implantation region 50, and may also be in contact with the bottoms and the side walls of the grooves 60. Compared with the existing device structure, the contact area between the ohmic metal 70 and the semiconductor (i.e., the semiconductor epitaxial layer) increases a part where the ohmic metal 70 is in contact with the sidewalls of the grooves 60, thereby achieving the purpose of increasing the contact area between the ohmic metal 70 and the semiconductor (i.e., the semiconductor epitaxial layer), and further effectively reducing the contact resistivity between the ohmic metal 70 and the semiconductor (i.e., the semiconductor epitaxial layer).

In the manufacturing method of the transistor with low contact resistivity provided by the embodiments of the present disclosure, the ion implantation region 50 are formed and activated in each of the source region and the drain region, which can achieve the purpose of reducing the contact resistivity of the subsequent ohmic metal 70. Moreover, by adopting the ion implantation, the ohmic metal can be prevented from being annealed at high temperature in the related art, so as to avoid generating a burr on a surface of the transistor and thus affecting the performance of the transistor. On this basis, by etching the activated ion implantation region 50 to form grooves 60, and depositing ohmic metal 70 in the grooves 60, the contact area between the ohmic metal 70 and the semiconductor (i.e., the semiconductor epitaxial layer) can be effectively increased without high-temperature annealing after depositing the ohmic metal 70, thereby further reducing the contact resistivity of the ohmic metal 70, and optimizing the performance of the transistor.

It should be understood that the size of a sequence number of each step in the above-mentioned embodiment does not mean the order of execution, and the order of execution of each process should be determined according to its function and internal logic, and the size of the sequence number of each step should not constitute any restrictions on the implementation process of the embodiments of the present disclosure.

In summary, the transistor with low contact resistivity and the manufacturing method therefor are provided by the embodiments of the present disclosure. The transistor includes a substrate 10, a buffer layer 20, a channel layer 30, and a barrier layer 40 stacked in sequence. The Ion implantation region 50 is respectively formed in the source region and the drain region of the barrier layer 40, and the grooves 60 are arranged at intervals in the ion implantation region 50, and the extension direction of each groove 60 is a direction from the barrier layer 40 to the channel layer 30. The ohmic metal 70 is deposited on the surface of the ion implantation region 50 and in each groove 60, and the ohmic metal 70 is in contact with the bottoms and the side walls of each groove 60. In this solution, through the grooves 60 formed in the ion implantation region 50, the ohmic metal 70 can be not only in contact with the surface of the ion implantation region 50, but also can be in contact with the side walls of the groove 60, thus increasing the contact area between the ohmic metal 70 and the semiconductor (i.e., the semiconductor epitaxial layer), further reducing the ohmic contact resistivity and improving the high-frequency characteristics of the transistors.

In addition, the ohmic contact resistivity can be further reduced by forming the ion implantation region 50, and an annealing process is not needed, thereby avoiding the problem that burrs are generated on a surface of the semiconductor transistor and thus the performance of the semiconductor transistor is affected.

The above is merely the specific embodiments of the present disclosure, but the scope of protection of the present disclosure is not limited thereto. Any change or replacement that can be easily thought of by a person familiar with this technical field within the scope disclosed in the scope of protection of the present disclosure should be covered by the present disclosure. Therefore, the scope of protection of the present disclosure should be based on the scope of protection of the claims.

What is claimed is:

1. A semiconductor transistor, comprising a semiconductor epitaxial layer,
wherein the semiconductor epitaxial layer comprises a channel layer and a barrier layer sequentially stacked on a substrate;
wherein at least one of a source region and a drain region of the semiconductor epitaxial layer is provided with an ion implantation region therein, and the ion implantation region is provided with a groove;
wherein ohmic metal is disposed on the ion implantation region, and the ohmic metal is in ohmic contact with a non-groove region of the ion implantation region, a sidewall of the groove, and a bottom of the groove; and
wherein an area of a vertical projection of the groove on the substrate is greater than or equal to half of an area of a vertical projection of the ohmic metal on the substrate; and a depth of the groove is less than a depth of the ion implantation region.

2. The semiconductor transistor according to claim 1, wherein implanted ions in the ion implantation region comprise at least one selected from the group consisting of silicon (Si) ions and germanium (Ge) ions.

3. The semiconductor transistor according to claim 1, wherein a position corresponding to a depth of ion implantation in the ion implantation region is located in the barrier layer.

4. The semiconductor transistor according to claim 1, wherein a position corresponding to a depth of ion implantation in the ion implantation region is located at a surface of the channel layer.

5. The semiconductor transistor according to claim 1, wherein the ion implantation region penetrates through the barrier layer and extends to the channel layer.

6. The semiconductor transistor according to claim 5, wherein the groove penetrates through the barrier layer and extends to the channel layer.

7. The semiconductor transistor according to claim 5, wherein the depth of the ion implantation region is less than 500 nanometers (nm).

8. The semiconductor transistor according to claim 1, wherein a shape of the vertical projection of the groove on the substrate is one of circular, square, rectangular, or irregular.

9. The semiconductor transistor according to claim 1, wherein a size of the vertical projection of the groove on the substrate is in a range from 1 micrometer (μm) to 100 μm.

10. The semiconductor transistor according to claim 1, wherein the groove in the ion implantation region is at least two in number.

11. The semiconductor transistor according to claim 10, the number of the at least two grooves is k, an area of a vertical projection of each of the at least two grooves on the substrate is a, the area of the vertical projection of the ohmic metal on the substrate is b, and 0.5≤(k×a)/b<1.

12. The semiconductor transistor according to claim 10, wherein a size of a vertical projection of each of the at least two grooves on the substrate is in a range from 1 μm to 100 μm.

13. The semiconductor transistor according to claim 10, wherein a size of a groove of the at least two grooves proximate to a gate region is larger than a size of a groove of the at least two grooves facing away from the gate region.

14. The semiconductor transistor according to claim 10, wherein a spacing between two adjacent grooves of the at least two grooves proximate to a gate region is smaller than a spacing between two adjacent grooves of the at least two grooves facing away from the gate region.

15. The semiconductor transistor according to claim 1, wherein the barrier layer is made of of AlGaN, and the channel layer is made of GaN.

16. A manufacturing method for a semiconductor transistor, comprising:
sequentially forming a substrate, a channel layer, and a barrier layer;
forming, by ion implantation, an ion implantation region in at least one of a source region and a drain region of the barrier layer;
etching the ion implantation region to define a groove, wherein a depth of the groove is less than that of the ion implantation region; and
depositing ohmic metal on the ion implantation region, wherein the ohmic metal is in ohmic contact with a non-groove region of the ion implantation region, a sidewall of the groove, and a bottom of the groove; and an area of a vertical projection of the groove on the substrate is greater than or equal to half of an area of a vertical projection of the ohmic metal on the substrate.

17. The manufacturing method for the semiconductor transistor according to claim 16, wherein the barrier layer is made of AlGaN, and the channel layer is made of GaN.

18. The manufacturing method for the semiconductor transistor according to claim 16, wherein implanted ions in the ion implantation region comprise at least one selected from the group consisting of Si ions and Ge ions.

19. The manufacturing method for the semiconductor transistor according to claim 16, wherein the ion implantation region penetrates through the barrier layer and extends to the channel layer.

20. The manufacturing method for the semiconductor transistor according to claim 16, wherein the groove penetrates through the barrier layer and extends to the channel layer.
